(19) United States
(12) Patent Application Publication
(10) Pub. No.: US 2026/0173907 A1
(43) Pub. Date: Jun. 18, 2026

(54) THREE-DIMENSIONAL FANOUT PACKAGING STRUCTURE FOR A SYSTEM-ON CHIP AND RELATED METHODS

(71) Applicant: Microsoft Technology Licensing, LLC, Redmond, WA (US)

(72) Inventors: Rahul AGARWAL, Livermore, CA (US); Sriram SRINIVASAN, Chandler, AZ (US); Charles BOECKER, Ames, IA (US)

(73) Assignee: Microsoft Technology Licensing, LLC, Redmond, WA (US)

(21) Appl. No.: 18/982,496

(22) Filed: Dec. 16, 2024

(51) Int. Cl. H10W 70/60; H10W 70/63; H10W 70/65

(52) U.S. Cl. CPC H10W 70/611; H10W 70/635; H10W 70/65

(57) ABSTRACT

The present invention relates to a system comprising a pair of System-on-Chip dies that includes through-silicon vias (TSVs) coupling the front side and the back side. A first fanout wafer with first fanout layers is coupled to the front side of the System-on-Chip dies and second fanout wafer with second fanout layers is coupled to the TSVs on the back side of the System-on-Chip dies. A carrier wafer is bonded to the second fanout wafer, collectively forming a 3D double-sided fanout structure that approximately doubles the available die-to-die routing bandwidth.

### BACKGROUND

A System-on-Chip (SoC) integrates multiple blocks of functionality in a single integrated circuit. For example, the SoC may include one or more processor cores, memory interfaces, network interfaces, optical interfaces, digital signal processors, graphics processors, telecommunications components, and the like. Traditionally, each of the blocks are created in one monolithic die. However, for various reasons, such as increasing the yield of functional chips or reducing design complexity and cost, it is increasingly common to separate these blocks into individual die and reconstitute them in a package. To achieve the efficiency and performance of a monolithic die, these individual dies should be highly interconnected. As the sizes of dies shrink and/or the number of input/output pins increases, it is becoming increasingly difficult to scale this connectivity, which may be expressed as die-to-die routing bandwidth.

Generally, three-dimensional (3D) packaging modules include multiple dies stacked vertically on top of each other. The dies in 3D packaging can be directly connected to each other with the bottom die directly connected to a package substrate. The top die in a 3D package can be connected to the package substrate using a variety of configurations including wire bonds and through-silicon vias (TSVs) through the bottom die.

One approach to SoC design and component reuse is the notion of a “chiplet.” A “chiplet” is a semiconductor die containing one or more functional circuit blocks, that have been specifically designed to work with other chiplets to form larger more complex chips. Die singulation, also called wafer dicing, is the process in semiconductor device fabrication by which dies are separated from a finished wafer of semiconductor. Die singulation comes after the photolithography process. It can involve scribing and breaking, mechanical sawing (normally with a machine called a dicing saw) or laser cutting. All methods are typically automated to ensure precision and accuracy. Chiplets are typically singulated from a finished semiconductor wafer to form SoC dies. To modularize system design and reduce complexity, these chiplets include functional circuit blocks.

The integration of various heterogenous chiplets in a single system can be challenging. For die-to-die partitioning between SoC dies, high density, short channel, wide interconnects are desirable. To address this, post-fabrication redistribution layers (RDL) or fanout layers have been fabricated on top of the chiplets, with fanout layers fabricated to form a fanout wafer. Fanout wafers have only limited ubump pitch available in the die-to-die connection areas of the SoC die in the chiplet, along with the number of fanout layers that are not able to scale further down in size and pitch. Given the limitations on die-to-die routing bandwidth between chiplets, it is desirable to provide a 3D double-sided fanout packaging structure for chiplets that increases the available die-to-die routing bandwidth using existing die-to-die connection areas.

### SUMMARY

In one general aspect, the present invention relates to a system comprising a System-on-Chip (SoC) die having a front side and a back side. The SoC die includes through-silicon vias (TSVs) coupling the front side and the back side. First fanout layers are coupled to the front side of the SoC die and second fanout layers are coupled to the TSVs on the back side of the SoC die. A carrier wafer is bonded to the second fanout layers.

The system may further include a second SoC die having a second front side and a second back side. The second SoC die includes through-silicon vias (TSVs) coupling the second front side and the back side. The first fanout layers are coupled to the front side of the SoC die and the second fanout layers are coupled to the TSVs on the back side of the System-on-Chip die, that approximately doubles the available die-to-die routing bandwidth between the first System-on-Chip die and the second System-on-Chip die.

In yet another general aspect, the present invention relates to a method of fabricating a 3D double-sided fanout structure that includes singulating a plurality of System-on-Chip dies, the System-on-Chip dies including TSVs and a BEOL layer fabricated on a front side of the System-on-Chip dies that are in turn bonded to a first temporary carrier on a back side. Further steps include processing the front side of the System-on-Chip dies to add first fanout layers coupled to the BEOL layer, bonding the first fanout layers to a second temporary carrier, de-bonding the System-on-Chip dies from the first temporary carrier on the back side, thinning the back side of the System-on-Chip dies to reveal the TSVs, processing the back side of the System-on-Chip dies to add second fanout layers coupled to the TSVs, bonding the second fanout layers to a carrier wafer, and de-bonding the second temporary carrier from the first fanout layers.

The method further comprises a second System-on-Chip die, the first and second System-on-Chip dies coupled to each other via the first fanout layer and the second fanout layer that approximately doubles an available die to die routing bandwidth between the first System-on-Chip die and the second System-on-Chip die.

In a further general aspect, the present invention relates to a method of fabricating a 3D double-sided fanout structure that includes singulating a plurality of System-on-Chip dies, the System-on-Chip dies including a first BEOL layer fabricated on a front side of the System-on-Chip dies, a second BEOL layer fabricated on a back side of the System-on-Chip dies, power-delivery-network rails embedded in the back side of the System-on-Chip dies, the power-delivery-network rails coupled to the second BEOL layer. A support carrier is bonded to the first BEOL layer. The method further includes reconstituting the plurality of System-on-Chip dies, processing the back side of the System-on-Chip dies to add first fanout layers coupled to the first BEOL layer, bonding the first fanout layers to a first carrier wafer, debonding the temporary carrier from the first BEOL layer of the System-on-Chip dies, thinning the front side of the plurality of System-on-Chip dies to reveal the first BEOL layer, processing the front side of the System-on-Chip dies to add second fanout layers coupled to the first BEOL layer, bonding the second fanout wafer to a second carrier wafer and then de-bonding the first carrier wafer from the first fanout layers.

The method further comprises placing a pair of System-on-Chip dies adjacent to each other, with the pair of System-on-Chip dies coupled to each other via the first fanout layers and the second fanout layers that approximately doubles an available die to die routing bandwidth between the pair of System-on-Chip dies.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject of this disclosure.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 depicts a view of a system including a System-on-Chip die including TSVs and a 3D double-sided fanout structure.

FIG. 2 depicts a view of a system including first System-on-Chip die coupled to a second System-on-Chip die via the 3D double-sided fanout structure, the first and second System-on-Chip dies including the TSVs.

FIGS. 3A-B depicts a view of two steps of the manufacturing process for forming the 3D double-sided fanout structure in the system of FIG. 2.

FIGS. 3C-D depicts a view of two steps of the manufacturing process for forming the 3D double-sided fanout structure in the system of FIG. 2.

FIGS. 3E-F depicts a view of two steps of the manufacturing process for forming the 3D double-sided fanout structure in the system of FIG. 2.

FIG. 4 depicts a view of a system including a System-on-Chip die including power-delivery-network rails and a 3D double-sided fanout structure.

FIG. 5 depicts a view of the system including first System-on-Chip die coupled to a second System-on-Chip die via the 3D double-sided fanout structure, the first and the second System-on-Chip dies including the power-delivery-network rails.

FIGS. 6A-B depicts a view of two steps of the manufacturing process for forming the 3D double-sided fanout structure in the system of FIG. 5.

FIGS. 6C-D depicts a view of two steps of the manufacturing process for forming the 3D double-sided fanout structure in the system of FIG. 5.

FIGS. 6E-F depicts a view of two steps of the manufacturing process for forming the 3D double-sided fanout structure in the system of FIG. 5.

FIG. 7 shows a flow process of a method for forming the 3D double-sided fanout structure in the system of FIG. 2.

FIG. 8 shows a flow process of a method for forming the 3D double-sided fanout structure in the system of FIG. 5.

### DETAILED DESCRIPTION

While the use of chiplets to build larger systems has resulted in higher yields and lower cost through the reuse of established functionality, there are limitations with the amount of routing bandwidth available between the System-on-Chip (SoC) dies in each of the chiplets that are becoming a barrier to continued performance gains. When forming a larger system, System-on-Chip dies are typically reconstituted, such that they are placed on a carrier wafer adjacent to each other and bonded in place on the carrier wafer, followed by filling the gaps between dies using organic or inorganic compounds. Fanout layers may then be fabricated on top of each of the System-on-Chip dies to provide the die-to-die signal routing, with a selected number of fanout layers. There is a limited amount of physical area available on each SoC die to provide connections to the fanout wafer. Simply adding more fanout layers to obtain more die-to-die routing bandwidth quickly reaches practical limitations that include increasing undesirable warpage of the package and encountering more difficulty in processing the top fanout layers.

It is desirable to obtain more die-to-die routing bandwidth between System-on-Chip dies that overcomes the existing limitations related to the use of fanout wafers and similar types of redistribution layers that are traditionally fabricated on or attached to the front side of the SoC dies. The present application describes the use of second fanout layers that are fabricated to the back side of the System-on-Chip dies that takes advantage of existing semiconductor fabrication methods to form a three dimensional (3D) double-sided fanout packaging structure that approximately doubles the die-to-die routing bandwidth between System-on-Chip dies compared with the existing bandwidth available in traditional single-sided fanout wafer structures.

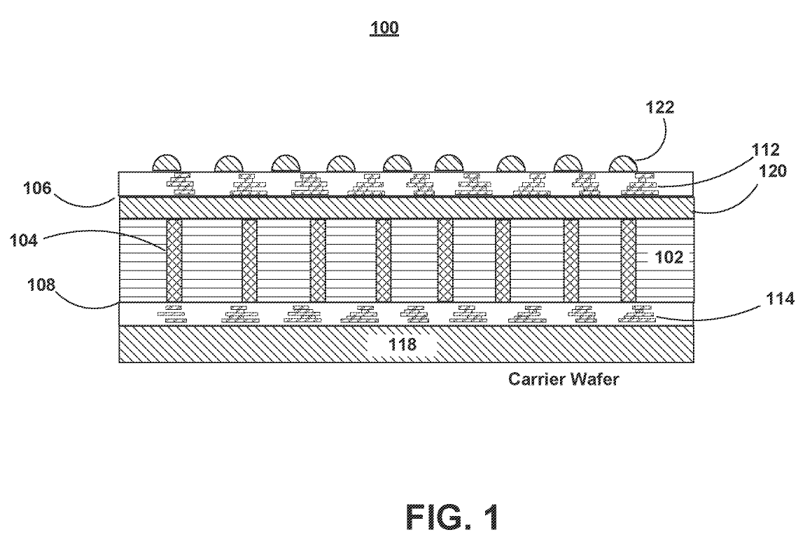

FIG. 1 illustrates a system 100 including a System-on-Chip die 102 that includes a plurality of through-silicon vias (TSVs) 104 vertically arranged throughout the System-on-Chip die 102 as determined by device design and interconnection requirements. The System-on-Chip die 102 includes a front side 106 and a back side 108. The TSVs 104 are vertical electrical connections, typically metal structures, that are designed to electrically couple the front side 106 to the back side 108 of the System-on-Chip die 102.

In integrated circuit fabrication, FEOL (front-end-of-line) is the first portion where individual components, such as transistors, capacitors, and resistors, are patterned in a silicon wafer. BEOL (back-end-of-line) is the second portion where various metallization layers are deposited onto the wafer to provide connections between the components.

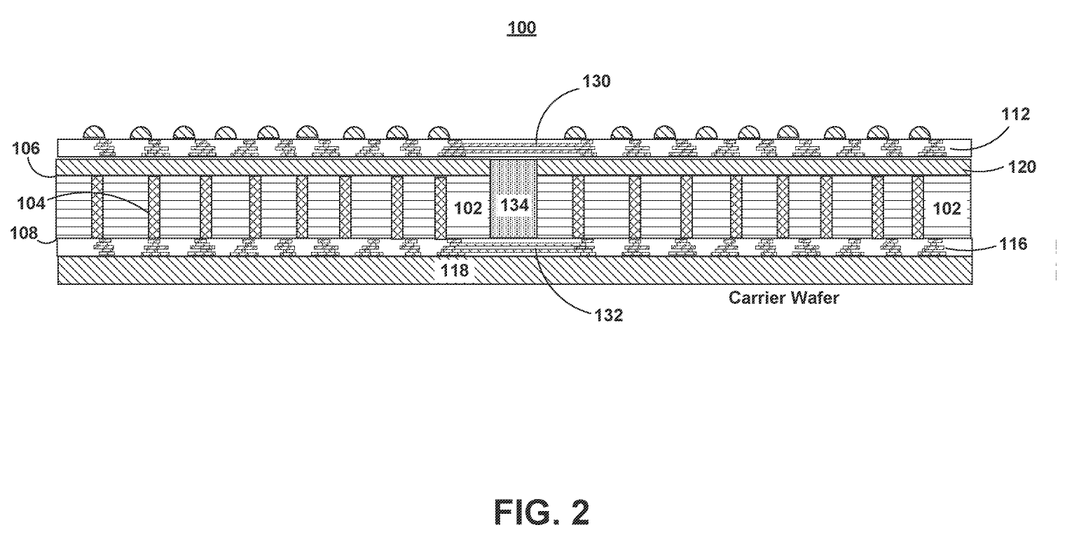

A BEOL layer 120 is fabricated on the front side 106 of the System-on-Chip die 102. First fanout layers 112 are coupled to the BEOL layer 120 and to the plurality of TSVs 104 on the front side 106 of the System-on-Chip die 102. The first fanout layers 112 may also be referred to generally as a redistribution layer (RDL) that provides interconnection pathways to points on the BEOL layer 120 within the System-on-Chip die 102 or spanning multiple System-on-Chip dies as will be shown in FIG. 2. Second fanout layers 116 are coupled to the back side 108 of the System-on-Chip die 102 and further coupled to the plurality of TSVs 104. A carrier wafer 118 is bonded to the second fanout layers 116 . A plurality of microbumps 122 are placed on and coupled to the first fanout layers 112. The number and placement of the microbumps 122 are determined by device design and interconnection requirements.

FIG. 2 illustrates the system 100 where a plurality of the System-on-Chip dies 102 as illustrated in FIG. 1 have been singulated and placed on the carrier wafer 118. Die singulation, also called wafer dicing, is the process in semiconductor device fabrication by which dies are separated from a finished semiconductor wafer. The System-on-Chip dies 102 are reconstituted on the carrier wafer 118 and embedded in an encapsulant material 134 during a mold process. The encapsulant material 134 fills the gap between each of the System-on-Chip dies 102 as part of the packaging process and may include materials like epoxy molding compound (EMC). The first fanout layers 112 are coupled to the BEOL layer 120 on the front side 106 of each of the System-on-Chip dies 102. The second fanout layers 116 are coupled to the back side 108 of each of the System-on-Chip dies 102. The first fanout layers 112 further include a bridge area 130 and the second fanout layers 116 further include a bridge area 132. The bridge areas 130 and 132 provide for the interconnection and routing between the System-on-Chip dies 102. The TSVs 104 couple the front side 106 including the BEOL layer 120 and the back side 108. The first fanout layers 112 and the second fanout layers 116 collectively form the 3D double-sided fanout structure that approximately doubles the available die-to-die routing bandwidth.

The first fanout layers 112 and the second fanout layers 116 as described could also be implemented in first and second fanout wafers (not shown), the first fanout wafer coupled to the BEOL layer 120 on the front side 106 of each of the System-on-Chip dies 102 and the second fanout wafer coupled to the back side 108 of each of the System-on-Chip dies 102, the first and second fanout wafers coupled to the System-on-Chip dies 102 via microbumps to collectively form the 3D double-sided fanout structure that approximately doubles the available die-to-die routing bandwidth.

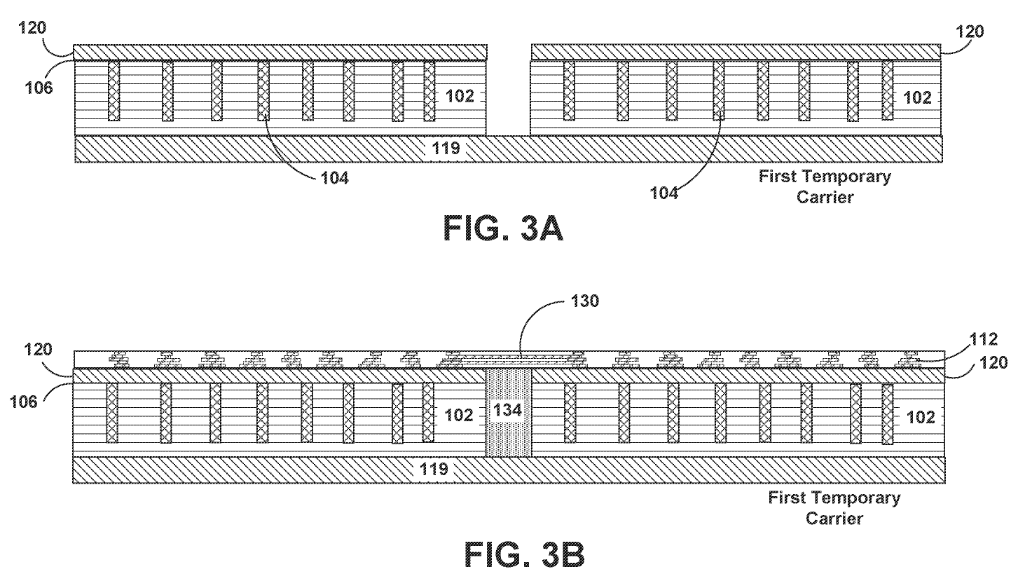

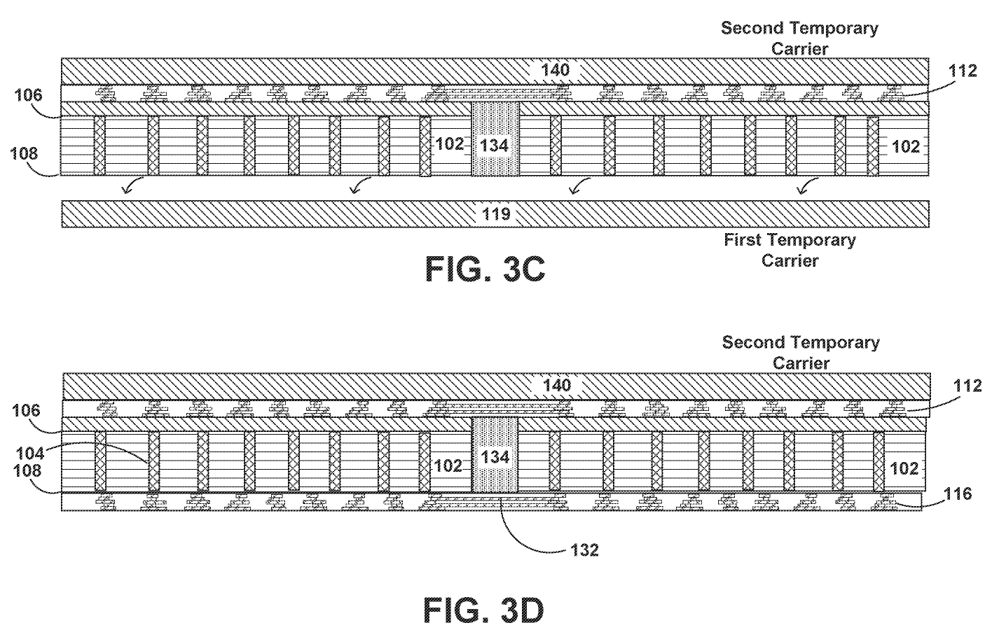

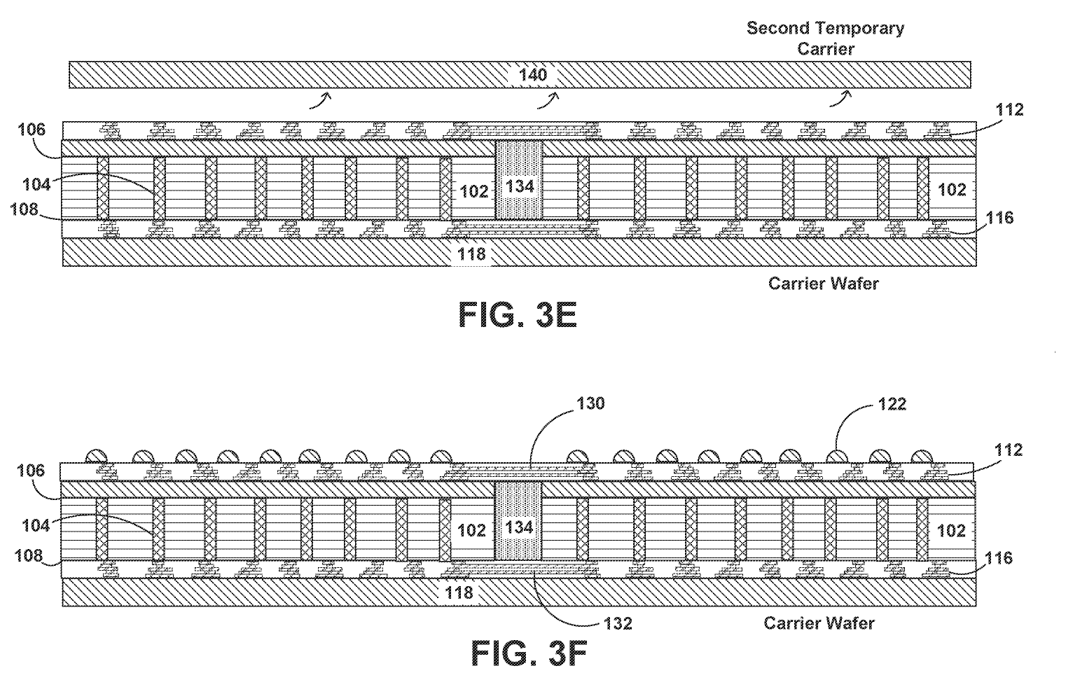

FIGS. 3A-Bdepicts a view of two steps of the manufacturing process for forming the 3D double-sided fanout structure in the system of FIG. 2. FIG. 3A shows the step of singulating a pair of System-on-Chip dies 102 which are separated from a finished semiconductor wafer. Each of the System-on-Chip dies 102 includes the BEOL layer 120 and the plurality of TSVs 104. The System-on-Chip dies 102 are placed on a first temporary carrier 119 in a horizontal fashion. FIG. 3B shows the step of reconstituting the System-on-Chip dies 102 that includes placing the pair of System-on-Chip dies 102 adjacent to each other on the first temporary carrier 119 and then adding the encapsulant material 134 in the gap between the pair of System-on-Chip dies 102 to bond their positions in the horizontal plan and facilitate the further processing steps described below. The next step includes processing each of the System-on-Chip dies 102 on the front side 106 to add the first fanout layers 112 including the bridge area 130 that is coupled to the BEOL layer 120.

FIGS. 3C-D depicts a view of the next two steps. FIG. 3C shows the step of bonding a second temporary carrier 140 to the first fanout layers 112 and then de-bonding the first temporary carrier 119 from the back side 108 of the System-on-Chip dies 102. The next step includes thinning the back side 108 of the System-on-Chip dies 102 which is a grinding operation that is performed to reveal the TSVs 104 enabling electrical connections. FIG. 3D shows the next step that includes processing the System-on-Chip dies 102 on the back side 108 to add the second fanout layers 116 including the bridge area 132 that are coupled to the TSVs 104.

FIGS. 3E-Fdepicts a view of the next two steps. FIG. 3E shows the step of bonding the second fanout layers 116 to a carrier wafer 118 and then de-bonding the second temporary carrier 140 from the first fanout layers 112. FIG. 3F shows the next step of adding the plurality of microbumps 122 coupled to the first fanout layers 112, with the number and placement of the microbumps 122 as determined by device design and interconnection requirements.

The resulting process steps shown in FIGS. 3A-F for the pair of System-on-Chip dies 102 now coupled to each other via the first fanout layers 112 on the front side 106 and the second fanout layers 116 on the back side 108 via the bridge areas 130 and 132 now collectively form the 3D double-sided fanout structure that approximately doubles the available die-to-die routing bandwidth.

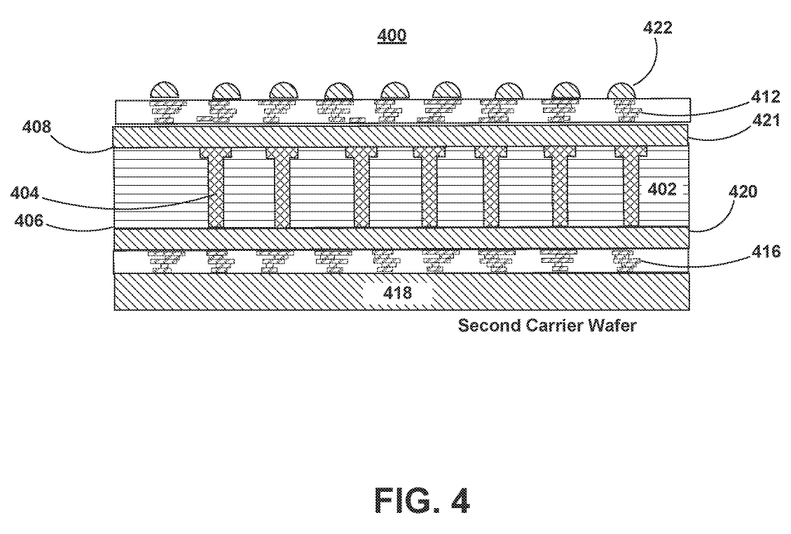

FIG. 4 illustrates an alternative approach to the system 100 of FIG. 1 as described below as system 400. The system 400 includes a System-on-Chip die 402 bonded to a second carrier wafer 418 that includes a power delivery network (PDN) comprising a plurality of power-delivery-network rails 404 vertically arranged throughout the System-on-Chip die 402 as determined by device design and interconnection requirements. The System-on-Chip die 402 includes a front side 406 and a back side 408. The power-delivery-network rails 404 distribute electrical power to desired locations within the System-on-Chip die 402 and provide vertical electrical connections, typically metal structures, that electrically couple the front side 406 to the back side 408 of the System-on-Chip die 402.

Power delivery networks (PDNs) are an emerging technology for backside power delivery in a System-on-Chip. Examples of PDNs offered by the semiconductor foundries include TSMC’s A16 node including its Super Power Rail™ and Intel’s PowerVia™. The present application advantageously leverages the capabilities of the PDN technology for coupling the front side 406 and the back side 408 of the System-on-Chip die 402 via the power-delivery-network rails 404 to implement the 3D double-sided fanout structure that approximately doubles the available die-to-die routing bandwidth, while requiring only minimal changes to existing wafer fabrication methods.

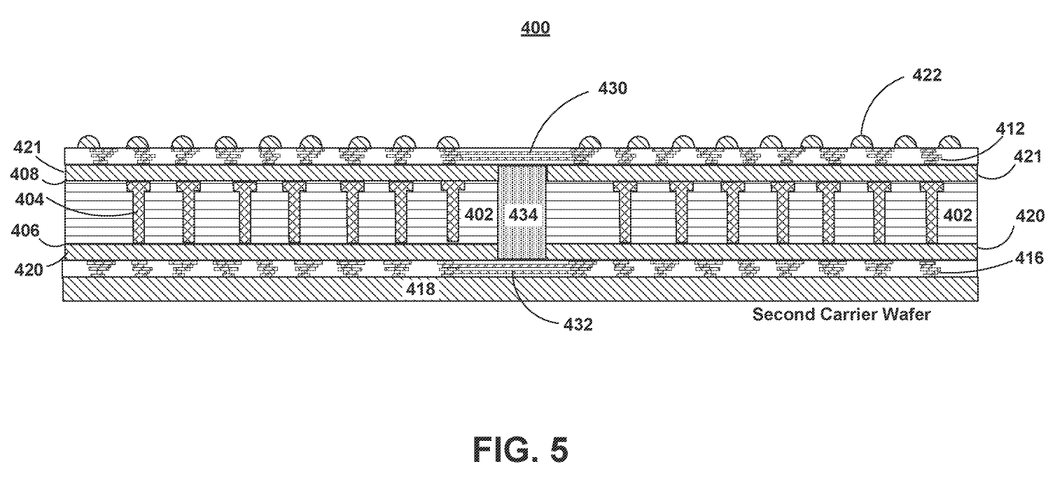

A first BEOL layer 420 is fabricated on the front side 406 of the System-on-Chip die 402 and a second BEOL layer 421 is fabricated on the back side 408 of the System-on-Chip die 402. First fanout layers 416 are coupled to the first BEOL layer 420 and to the plurality of power-delivery-network rails 404 on the front side 406 of the System-on-Chip die 402. Second fanout layers 412 are coupled to the back side 408 of the System-on-Chip dies 402 and is further coupled to the plurality of the power-delivery-network rails 404. The second fanout layers 412 and the first fanout layers 416 may also be referred to generally as redistribution layers (RDL) that provide interconnection pathways to points among the first BEOL layer 420 and the second BEOL layer 421 within the System-on-Chip die 402 or spanning multiple System-on-Chip dies 402 as will be shown in FIG. 5. A second carrier wafer 418 is bonded to the first fanout layers 416. A plurality of microbumps 422 is placed on and coupled to the second fanout layers 412, with the number and placement of the microbumps 422 as determined by device design and interconnection requirements.

FIG. 5 illustrates the system 400 in which a plurality of the System-on-Chip dies 402 as illustrated in FIG. 4 have been singulated and reconstituted on the second carrier wafer 418 and embedded in an encapsulant material 434 during a mold process. The encapsulant material 434 fills the spaces between each of the System-on-Chip dies 402 as part of the packaging process. The first fanout layers 416 are coupled to the first BEOL layer 420 on the front side 406 of the System-on-Chip dies 402. The second fanout layers 412 are coupled to the back side 408 of the System-on-Chip dies 402. The first fanout layers 416 further include a bridge area 432 and the second fanout layers 412 further include a bridge area 430. The bridge areas 430 and 432 provide for the interconnection and routing between the plurality of System-on-Chip dies 402. The power-delivery-network rails 404 couple the front side 406 including the first BEOL layer 420 and the second BEOL layer 421 in the back side 408 of the System-on-Chip dies 402. The first fanout layers 416, the second fanout layers 412, and the bridge areas 430 and 432 collectively form the 3D double-sided fanout structure that approximately doubles the available die-to-die routing bandwidth.

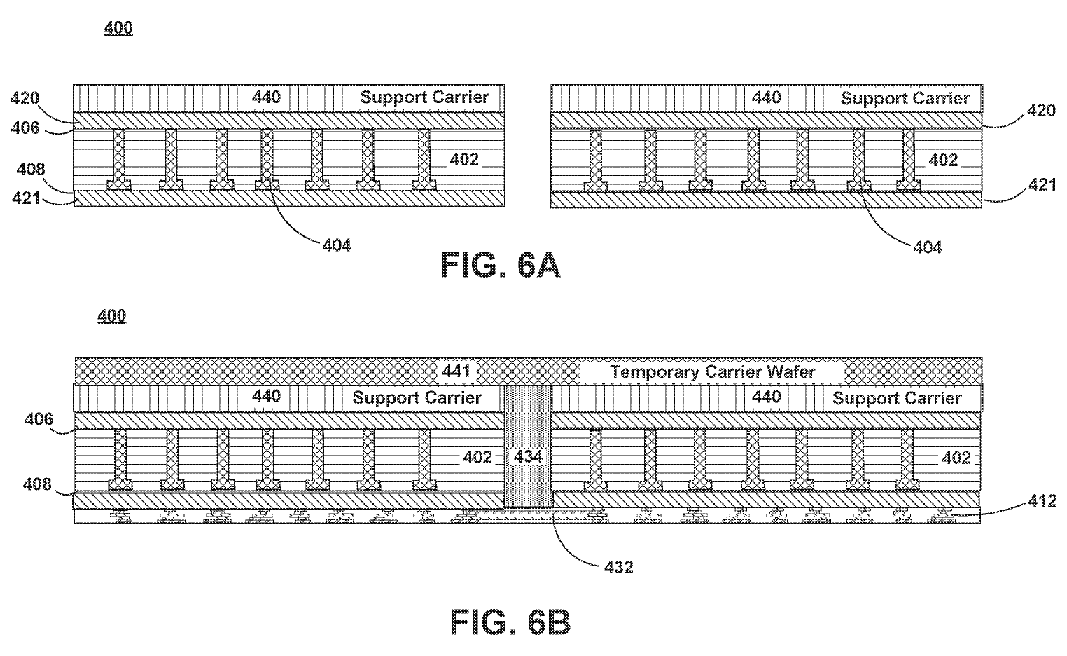

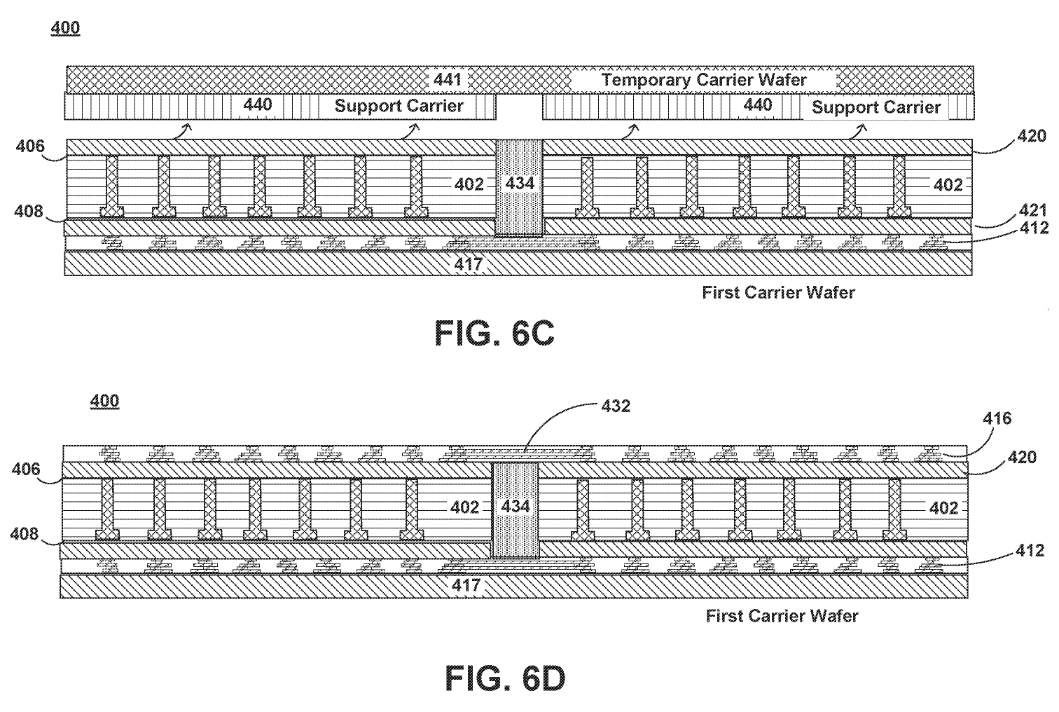

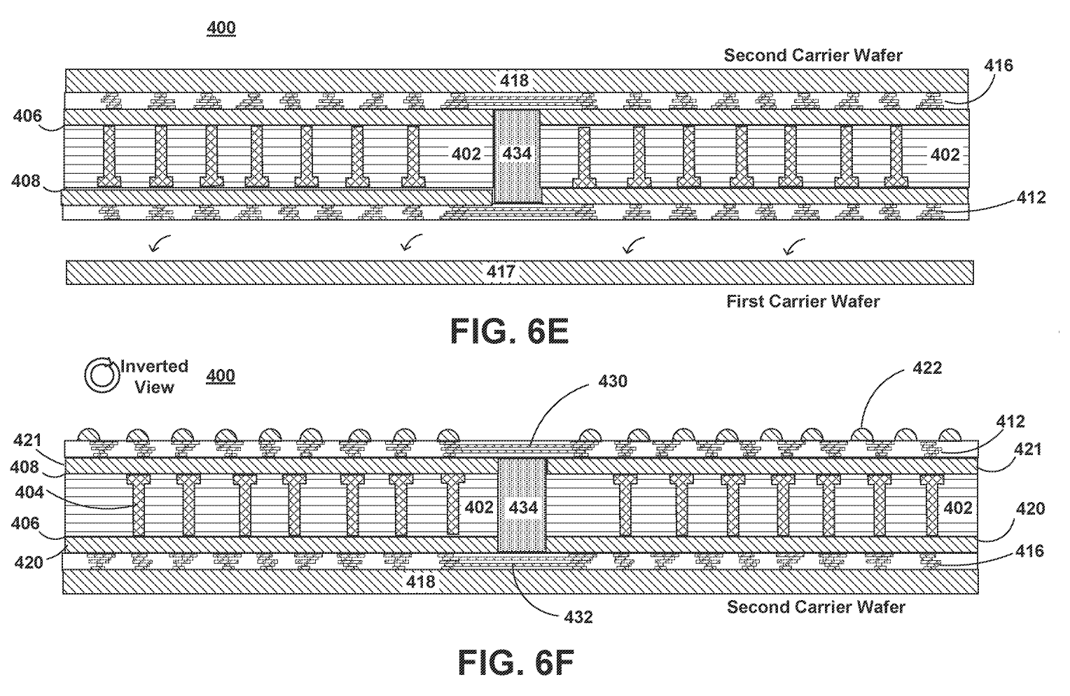

FIGS. 6A-B depicts a view of two steps of the manufacturing process for forming the 3D double-sided fanout structure in the system of FIG. 5. FIG. 6A shows the step of singulating a pair of System-on-Chip dies 402 which are separated from a finished semiconductor wafer. The System-on-Chip dies 402 include the first BEOL layer 420 and the plurality of power-delivery-network rails 404. The first BEOL layer 420 of the System-on-Chip dies 402 are bonded to a support carrier 440 with the pair of System-on-Chip dies 402 arranged in a horizontal fashion adjacent to each otheron a temporary carrier wafer 441. FIG. 6B shows the step reconstituting the System-on-Chip dies 402 that includes placing the pair of System-on-Chip dies 402 adjacent to each other and then adding the encapsulant material 434 in the gap between the pair of System-on-Chip dies 402 to bond their positions in the horizontal plane and facilitate the further processing steps described below. The next step includes processing each of the System-on-Chip dies 402 on the back side 408 to add the second fanout layers 412 including the bridge area 430 that are coupled to the power-delivery-network rails 404.

FIGS. 6C-D depicts a view of the next two steps. FIG. 6C shows the step of bonding the second fanout layers 412 on the back side 408 of the pair of System-on-Chip dies 402 to a first carrier wafer 417. The next step includes de-bonding the temporary carrier wafer 441 and removing (removing may include grinding, thinning or similar methods ), the support carrier 440 from the first BEOL layer 420 on the front side 406 of the System-on-Chip dies 402. Thinning may be performed by a grinding operation to reveal the metalization within the first BEOL layer 420. FIG. 6D shows the next step that includes processing each of the System-on-Chip dies 402 on the front side 406 to add the first fanout layers 416 including the bridge area 432 that is coupled to the first BEOL layer 420.

FIGS. 6E-F depicts a view of the next two steps. FIG. 6E shows the step of bonding the second carrier wafer 418 to the first fanout layers 416. The next step includes de-bonding the first carrier wafer 417 from the second fanout layers 412.

As illustrated in FIG. 6F, the system 400 is shown as an inverted view from the FIG. 6E, with the second carrier wafer 418 appearing at the bottom of the figure. This inverted view is shown for clarity and does not correspond to a physical process step in the fabrication process. The next step includes adding the plurality of microbumps 422 coupled to the second fanout layers 412, with the number and placement of the microbumps 422 as determined by device design and interconnection requirements.

The resulting process steps shown in FIGS. 6A-F for the pair of System-on-Chip dies 402 now coupled to each other via the first fanout layers 416 on the front side 406 and the second fanout layers 412 on the back side 408 via the bridge areas 430 and 432, now collectively form the 3D double-sided fanout structure that approximately doubles the available die-to-die routing bandwidth.

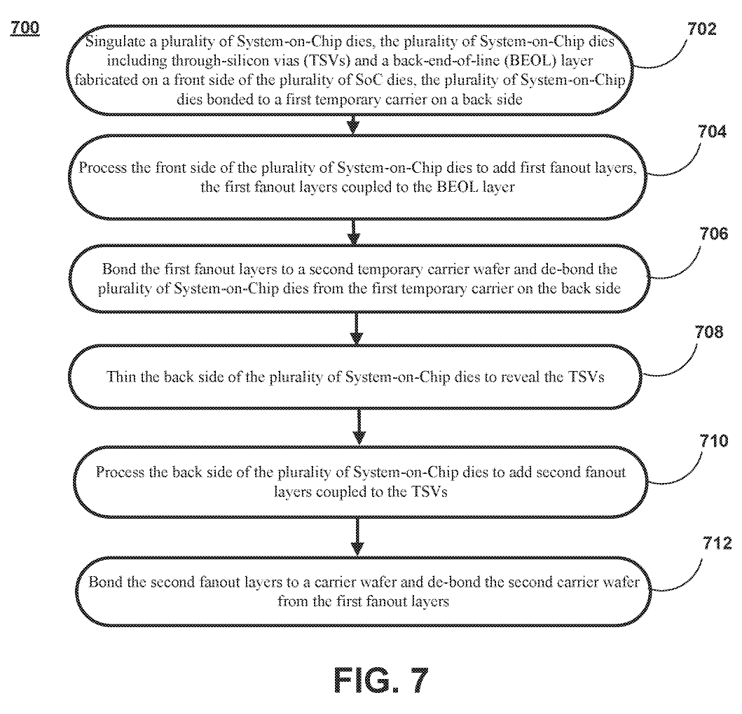

FIG. 7 shows a flow process 700 of a method for forming the 3D double-sided fanout structure in the system 100 of FIG. 2. The flow process 700 includes Step 702 for singulating a plurality of System-on-Chip dies 102 which are separated from a finished semiconductor wafer and bonded to a first temporary carrier 119 on a back side 108. Each of the plurality of System-on-Chip dies 102 includes the BEOL layer 120 fabricated on the front side 106 and the plurality of TSVs 104 as shown in FIG. 3A. Further, reconstituting the plurality of the System-on-Chip dies 102 includes placing the plurality of System-on-Chip dies 102 adjacent to each other and then adding the encapsulant material 134 in the gap between plurality of the System-on-Chip dies 102 as shown in FIG. 3B to bond their positions in the horizontal plane and facilitate the further processing steps described below.

The flow process 700 further includes Step 704 as further shown in FIG. 3B. This step includes processing the System-on-Chip dies 102 on the front side 106 to add the first fanout layers 112 that are coupled to the BEOL layer 120. The first fanout layers 112 further include a bridge area 130. The bridge area 130 provide for the interconnection and routing between the System-on-Chip dies 102.

Step 706, as shown in FIG. 3C, includes bonding a second temporary carrier 140 to the first fanout layers 112. The step further includes de-bonding the first temporary carrier 119 from the back side 108 of the System-on-Chip dies 102. The first fanout layers 112 may also be referred to generally as a redistribution layer (RDL) that provides interconnection pathways to points on the BEOL layer 120 within the System-on-Chip die 102 or spanning a plurality of System-on-Chip dies 102.

Step 708 shows the step of thinning the back side 108 of each of the System-on-Chip die 102. This may be performed by a grinding operation. In one implementation, the grinding operation is performed to reveal the TSVs 104 enabling electrical connections as further shown in FIG. 3C.

Step 710, as shown in FIG. 3D, includes processing each of the System-on-Chip dies 102 on the back side 108 to add the second fanout layers 116 including the bridge area 132 that are coupled to the TSVs 104. The System-on-Chip dies 102 are reconstituted on the carrier wafer 118 and embedded in an encapsulant material 134 during a mold process. The encapsulant material 134 fills the gap between the System-on-Chip dies 102 as part of the packaging process and may include materials like epoxy molding compound (EMC).

Step 712 shows the step of bonding the second fanout layers 116 to a carrier wafer 118 and de-bonding the second temporary carrier from the first fanout layers 112 on the front side 106 of the System-on-Chip dies 102 as shown in FIG. 3E. This step may further include adding the plurality of microbumps 122 coupled to the first fanout layers 112. The number and placement of the microbumps 122 may be determined by device design and interconnection requirements as shown in FIG. 3F.

The resulting process steps shown in the flow process 700 for the System-on-Chip dies 102 now coupled to each other via the first fanout layers 112 on the front side 106 and the second fanout layers 116 on the back side 108 via the bridge areas 130 and 132 now collectively form the 3D double-sided fanout structure that approximately doubles the available die-to-die routing bandwidth between the System-on-Chip dies 102.

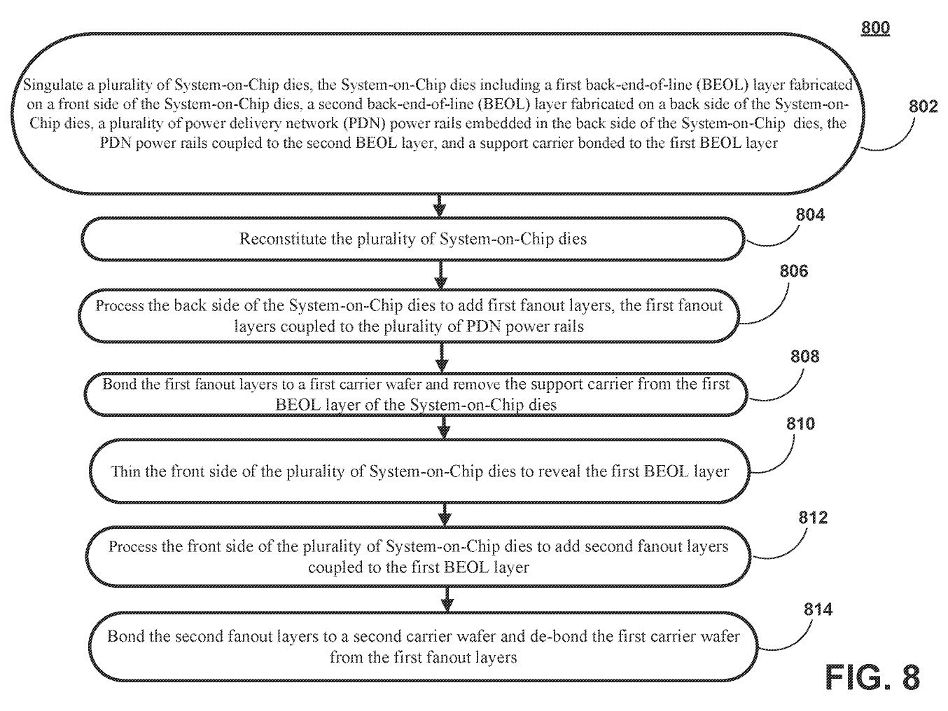

FIG. 8 shows a flow process 800 of a method for forming the 3D double-sided fanout structure of the system 400 of FIG. 5. The flow process 800 includes the Step 802 for singulating a plurality of System-on-Chip dies 402, which are separated from a finished semiconductor wafer. The System-on-Chip dies 402 include the first BEOL layer 420 on the front side 406 and the second BEOL layer 421 on the back side 408, and the plurality of power-delivery-network rails 404 shown in FIG. 6A. The first BEOL layer 420 is bonded to a support carrier 440 with the System-on-Chip dies 402 arranged in a horizontal plane adjacent to each other. System-on-Chip dies 402 includes a power delivery network (PDN) comprising a plurality of power-delivery-network rails 404 vertically arranged throughout the System-on-Chip dies 402 as determined by device design and interconnection requirements.

The flow process 800 further includes Step 804 as further shown in FIG. 6B. Reconstituting the System-on-Chip dies 402 includes placing the System-on-Chip dies 402 adjacent to each other in a horizontal plane and then adding the encapsulant material 434 in the gap between the the System-on-Chip dies 402 to bond their positions in the horizontal plane and facilitate the further processing steps described below.

Step 806 shows the step as further shown in FIG. 6C. This step further includes processing the System-on-Chip dies 402 on the back side 408 to add the first fanout layers 416 including the bridge area 432 that are coupled to the power-delivery-network rails 404.

Step 808 shows the step as further shown FIG. 6C. This step includes bonding the first fanout layers 416 to the first carrier wafer 417 and de-bonding the temporary carrier wafer 441 and removing the support carrier 440 from the first BEOL layer 420. The System-on-Chip dies 402 are reconstituted on the second carrier wafer 418 and embedded in an encapsulant material 434 during a mold process. The encapsulant material 434 fills the spaces between the System-on-Chip dies 402 as part of the packaging process.

Step 810 shows an additional step as further shown in FIG. 6C. The step includes thinning the front side 406 of the System-on-Chip dies 402. Thinning involves a grinding operation that is performed to reveal the metallization within the first BEOL layer 420.

Step 812 shows the step as further shown in FIG. 6D. The step includes processing the System-on-Chip dies 402 on the front side 406 to add the second fanout layers 412 including the bridge area 432 that are coupled to the first BEOL layer 420. The second fanout layers 412 also be referred to generally as a redistribution layer (RDL) that provides interconnection pathways to points on the first BEOL layer 420 within the System-on-Chip die 402 or spanning the plurality of System-on-Chip dies 402.

Step 814 shows the step as further shown in FIG. 6E. The step includes bonding the first fanout layers 416 to the second carrier wafer 418 and de-bonding the first carrier wafer 417 from the second fanout layers 412. The step may further include adding the plurality of microbumps 422 coupled to the second fanout layers 412. The number and placement of the microbumps 422 may be determined by device design and interconnection requirements as shown in FIG. 6F.

The resulting flow process steps shown in Steps 800-814 for the pair of System-on-Chip dies 402 now coupled to each other via the first fanout layers 416 on the front side 406 and the second fanout layers 412 on the back side 408 via the bridge areas 430 and 432 now collectively form the 3D double-sided fanout structure that approximately doubles the available die-to-die routing bandwidth.

While various embodiments have been described, the description is intended to be exemplary, rather than limiting, and it is understood that many more embodiments and implementations are possible that are within the scope of the embodiments. Although many possible combinations of features are shown in the accompanying figures and discussed in this detailed description, many other combinations of the disclosed features are possible. Any feature of any embodiment may be used in combination with or substituted for any other feature or element in any other embodiment unless specifically restricted. Therefore, it will be understood that any of the features shown and/or discussed in the present disclosure may be implemented together in any suitable combination. Accordingly, the embodiments are not to be restricted except in light of the attached claims and their equivalents. Also, various modifications and changes may be made within the scope of the attached claims.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element. Furthermore, subsequent limitations referring back to “said element” or “the element” performing certain functions signifies that “said element” or “the element” alone or in combination with additional identical elements in the process, method, article or apparatus are capable of performing all of the recited functions.

The disclosure provides many different embodiments, or examples, for implementing different features of the provided subject matter. Specific examples of components and arrangements are described to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A system comprising:
a System-on-Chip die having a front side and a back side,
a plurality of through-silicon vias (TSVs) included within the System-on-Chip die and coupling the front side and the back side of the System-on-Chip die;
first fanout layers coupled to the front side of the System-on-Chip die;
second fanout layers coupled to the TSVs on the back side of the System-on-Chip die; and
a carrier wafer bonded to the first fanout layers or the second fanout layers.

2. The system of claim 1, wherein the System-on-Chip die is singulated and reconstituted on the carrier wafer.

3. The system of claim 2, further comprising a second System-on-Chip die, the second System-on-Chip die having a second front side and a second back side, the first fanout layers coupled to the second front side of the second System-on-Chip die, and the second fanout layers coupled to the second back side of the second System-on-Chip die, that approximately doubles an available die-to-die routing bandwidth between the System-on-Chip die and the second System-on-Chip die.

4. The system of claim 3, wherein the first fanout layers include a first bridge area between the System-on-Chip die and the second System-on-Chip die and the second fanout layers include a second bridge area between the System-on-Chip die and the second System-on-Chip die.

5. The system of claim 3, further comprising encapsulant material in a gap between the System-on-Chip die and the second System-on-Chip die.

6. The system of claim 1, further comprising a back-end-of-line (BEOL) layer fabricated on the front side of the System-on-Chip die, the back-end-of-line (BEOL) layer coupled to the first fanout layers and the second fanout layers.

7. The system of claim 6, the System-on-Chip die further comprising:
a second back-end-of-line (BEOL) layer fabricated on the back side of the System-on-Chip die, the second back-end-of-line (BEOL) layer coupled to the first fanout layers and a second fanout layers; and
a plurality of power-delivery-network rails embedded in the back side of the System-on-Chip die, the plurality of power-delivery-network rails coupled to the back-end-of-line (BEOL) layer and the second back-end-of-line (BEOL) layer, wherein the second fanout layers are coupled to the second back-end-of-line (BEOL) layer on the back side of the System-on-Chip die.

8. The system of claim 1 further including microbumps coupled to the first fanout layers on the front side of the System-on-Chip die.

9. A method comprising:
singulating a plurality of System-on-Chip dies, the plurality of System-on-Chip dies including through-silicon vias (TSVs) and a back-end-of-line (BEOL) layer fabricated on a front side of the plurality of System-on-Chip dies, the plurality of System-on-Chip dies bonded to a first temporary carrier on a back side;
processing the front side of the plurality of System-on-Chip dies to add first fanout layers, the first fanout layers coupled to the back-end-of-line (BEOL) layer;
bonding the first fanout layers to a second temporary carrier and de-bonding the plurality of System-on-Chip dies from the first temporary carrier on the back side;
thinning the back side of the plurality of System-on-Chip dies to reveal the TSVs;
processing the back side of the plurality of System-on-Chip dies to add second fanout layers coupled to the TSVs; and
bonding the second fanout layers to a carrier wafer and de-bonding the second temporary carrier from the first fanout layers.

10. The method of claim 9, further comprising reconstituting the plurality of System-on-Chip dies.

11. The method of claim 10, further comprising placing plurality of System-on-Chip dies adjacent to each other wherein the plurality of System-on-Chip dies are coupled to each other via the first fanout layers and the second fanout layers, that approximately doubles an amount of die-to-die routing bandwidth between the plurality of System-on-Chip dies.

12. The method of claim 11, further comprising placing an encapsulant material in a gap between the plurality of System-on-Chip dies.

13. The method of claim 11, wherein the first fanout layers include a first bridge area between a System-on-Chip die and a second System-on-Chip die and the second fanout layers include a second bridge area between the plurality of System-on-Chip dies.

14. The method of claim 9, further comprising adding microbumps coupled to the first fanout layers on the front side.

15. A method comprising:
singulating a plurality of System-on-Chip dies, the plurality of System-on-Chip dies including a first back-end-of-line (BEOL) layer fabricated on a front side of the plurality of System-on-Chip dies, a second back-end-of-line (BEOL) layer fabricated on a back side of the plurality of System-on-Chip dies, a plurality of power-delivery-network rails embedded in the back side of the plurality of System-on-Chip dies, the plurality of power-delivery-network rails coupled to the second back-end-of-line (BEOL) layer, and a support carrier bonded to the first back-end-of-line (BEOL) layer;
reconstituting the plurality of System-on-Chip dies;
processing the back side of the plurality of System-on-Chip dies to add first fanout layers, the first fanout layers coupled to the plurality of power-delivery-network rails;
bonding the first fanout layers to a first carrier wafer and removing the support carrier from the first back-end-of-line (BEOL) layer of the plurality of System-on-Chip dies;
thinning the front side of the plurality of System-on-Chip dies to reveal the first back-end-of-line (BEOL) layer;
processing the front side of the plurality of System-on-Chip dies to add second fanout layers coupled to the first back-end-of-line (BEOL) layer; and
bonding the second fanout layers to a second carrier wafer and de-bonding the first carrier wafer from the first fanout layers.

16. The method of claim 15, further comprising dicing the plurality of System-on-Chip dies.

17. The method of claim 15, further comprising placing a pair of System-on-Chip dies adjacent to each other wherein the pair of System-on-Chip dies are coupled to each other via the first fanout layers and the second fanout layers, that approximately doubles an amount of die-to-die routing bandwidth between the pair of System-on-Chip dies.

18. The method of claim 17, further comprising placing an encapsulant material in a gap between the pair of System-on-Chip dies.

19. The method of claim 18, wherein the first fanout layers include a first bridge area between the pair of System-on-Chip dies and the second fanout layers include a second bridge area between the pair of System-on-Chip dies.

20. The method of claim 19, further comprising adding microbumps coupled to the first fanout layers on the back side.
